(19) United States
(12) Patent Application Publication
(10) Pub. No.: US 2019/0145608 A1
(43) Pub. Date: May 16, 2019

(54) LED Light Engine

(71) Applicant: General LED Opco, LLC, San Antonio, TX (US)

(72) Inventors: Aaron Gorman, New Braunfels, TX (US); Qi Hong, San Antonio, TX (US); Gray Lankford, San Antonio, TX (US)

(73) Assignee: General LED Opco, LLC, San Antonio, TX (US)

(21) Appl. No.: 16/182,870

(22) Filed: Nov. 7, 2018

Related U.S. Application Data
(60) Provisional application No. 62/584,224, filed on Nov. 10, 2017.

(51) Int. Cl. F21V 19/00; F21V 5/04; F21V 23/00; F21V 31/00; H05K 1/18; H05K 7/14; G09F 13/22

(52) U.S. Cl. CPC F21V 19/0055; F21V 5/04; F21V 23/001; F21Y 2115/10; H05K 1/181; H05K 7/1427; G09F 13/22; F21V 31/005

(57) ABSTRACT

A durable LED light engine includes a printed circuit board including LEDs mounted thereon positioned between a top enclosure and a bottom enclosure. Once assembled together, the combination of the top enclosure, the printed circuit board and the bottom enclosure are held together with a molding material. The top enclosure includes one or more integrated lenses for directing the illumination of the LEDs. The LED light engine may be mounted to a surface using a fastener passing through the combination of the top enclosure, the printed circuit board, and the bottom enclosure in the assembled LED light engine.

### CLAIM OF PRIORITY TO PRIOR APPLICATION

The present application claims the benefit of prior filed U.S. Provisional Application, Ser. No. 62/584,224, filed Nov. 10, 2017. By this reference, the full disclosure, including the drawings and any claims, of U.S. Provisional Application, Ser. No. 62/584,224, is incorporated herein as though now set forth in its entirety.

### BACKGROUND

### 1. Technical Field

The disclosed invention relates to a device for using light emitting diodes (“LED”) to illuminate signage. More particularly, the present invention relates to a light engine which is attached to other similar light engines to form a string of light engines typically used for retail and commercial sign illumination but may be used for interior lighting, point of sale lighting, and merchandising displays.

### 2. Related Art

Conventional flexible lighting systems that incorporate strings of LED light engines are typically used to provide illumination for cabinet or channel letter signs. Such strings of LED light engines are particularly useful for providing uniform illumination around the edges of a sign, as well as with irregularly shaped signage. However, in irregularly shaped signage, the irregular shape of the sign makes it difficult to obtain uniform illumination.

Several LED light engines in the relevant field have screws to hold together the module parts. However, there are problems with the effects of the screw load on the modules. The screw load is imparted on the printed circuit boards which can cause trace cracking and solder cracking. This can create leaking issues and, in some cases, damage the circuit board or even cause the circuit board to break.

Current LED light engines have limits in efficiency and manufacturing difficulty. For example, total internal reflection (TIR) lenses focus light into a small angle, resulting in a hot spot, a bright line along the opposite edge, and low brightness in the lightbox's center. TIR lenses have micro-prisms to spread out light between modules, which lowers optical efficiency. These lenses are difficult to manufacture, integrate into modules, and are costly to produce.

Accordingly, there remains a need in the art for a durable LED light engine that can be connected to other durable light engines to form a string of light engines that enables uniform sign edge illumination as well as uniform illumination with irregularly shaped signage.

### SUMMARY OF THE INVENTION

The durable LED light engine of the present invention can be connected to other durable light engines to form a string of light engines that enable uniform illumination even in irregularly shaped signage. To enable a more thorough understanding of some aspects of the presently disclosed embodiments, reference is made to the pending U.S. Non-Provisional Patent Application, Ser. No. 15/471,213, filed on Mar. 28, 2017, which is hereby incorporated by reference into the present disclosure.

The LED light engine of the present invention is constructed around a printed circuit board having LEDs positioned on the top surface thereof and wires attached to electronic componentry preferably positioned on the bottom surface thereof; however, some or all the wires and electronic componentry may be positioned on the top surface of the printed circuit board if desired. Covering the printed circuit board is a top enclosure. The top enclosure has one or more lenses formed on a top surface thereof. In some embodiments, one lens may be positioned over one or more LEDs in the assembled LED light engine. In other embodiments, the opening to each lens is constructed and arranged to be positioned over an LED in the assembled LED light engine. Each lens can be any convenient shape which provides the desired illumination, but in preferred embodiments, each lens is a free-form optic. The lenses are shaped so as to direct the illumination as needed for particular lighting configurations. The lenses tailor beam patterns in order to spread out light uniformly across the lightbox and direct light towards the module face, not to the opposite edge. They minimize hot spots, increase uniformity for long distances, improve optical efficiency, and are easier to manufacture and integrate within housing modules.

In some of the disclosed embodiments, the top enclosure includes a screw hole having a mounting screw which passes therethrough. The mounting screw also passes through an adjacent hole aligned in the printed circuit board. Underneath the printed circuit board is a bottom enclosure. In the disclosed embodiments, the bottom enclosure is formed as a substantially U-shaped enclosure. The bottom enclosure includes a projection which receives the mounting screw which passes through the bottom of the bottom enclosure so as to contact and enter a mounting surface onto which the LED light engine is to be attached.

After the printed circuit board is placed between the top enclosure and the bottom enclosure, the combination of the top enclosure, the printed circuit board, and the bottom enclosure are placed in a mold used in a molding machine. A molten sealant material is then injected onto the combination of the top enclosure, the printed circuit board, and the bottom enclosure. Once cooled, the molten plastic sealant material forms strain reliefs around, and covers the insulated wires positioned on the bottom of the printed circuit board. The molten sealant material is preferably a thermoplastic elastomer that can operate at high temperatures for a long lifetime. The molding process is referred to as “overmolding” and results in improved bonding, UV resistance, and operability in an increased temperature range. The overmolding also reduces the likelihood of moisture leaks. In some disclosed embodiments, the molten plastic sealant material affixes the top enclosure, the printed circuit board, and the bottom enclosure one to another. In some of these embodiments, the sealant material does not contact the printed circuit board.

### BRIEF DESCRIPTION OF THE DRAWING FIGURES

A better understanding of the LED light engine 10 of the present invention may be had by reference to the drawing figures wherein:

FIG. 1 is a top perspective view of a completed LED light engine 10;

FIG. 2 is an exploded view of the LED light engine 10 shown in FIG. 1;

FIG. 3 is a cross-sectional view of the LED light engine at line 3-3 of FIG. 1 showing the location of the cooled plastic sealant material 70;

FIG. 4 is a top plan view of the LED light engine 10 of FIG. 1.

### DESCRIPTION OF THE EMBODIMENTS

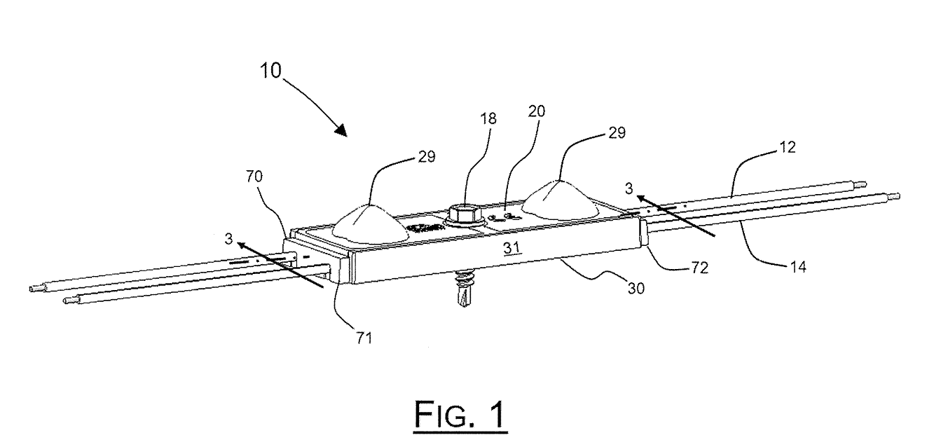

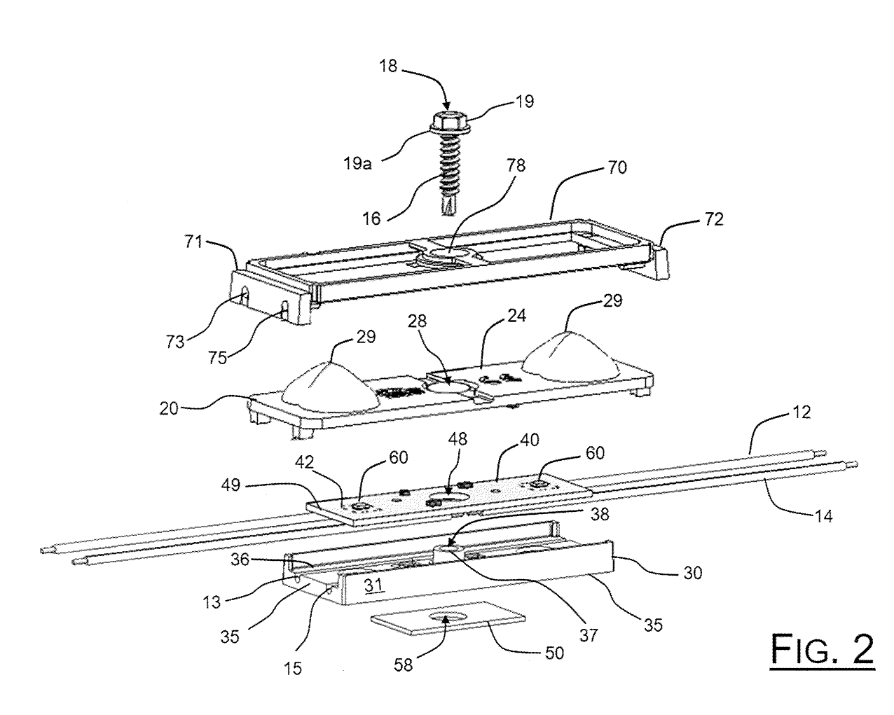

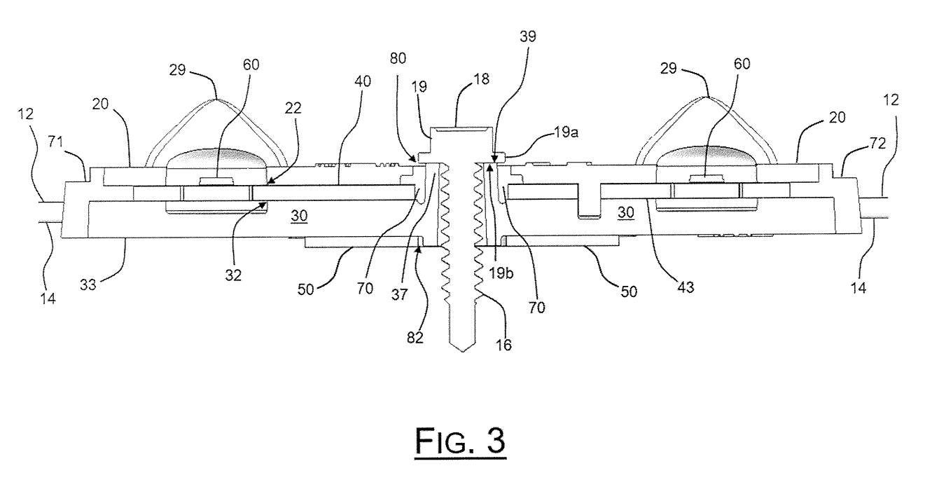

The present disclosure enables a durable LED light engine 10 that may be used for illuminating signage. Turning first to FIG. 1, there is represented an assembled LED light engine 10. As shown in FIG. 1, the top of the LED light engine 10 is a top enclosure 20. Included in and integrated with the top enclosure 20 are lenses 29. These lenses 29 are located over the LEDs 60 (shown in FIG. 2 and FIG. 3). Lenses 29 are spaced apart from one another on the surface of LED light engine 10. The placement of lenses 29 may allow for more uniform illumination when multiple LED light engines 10 are connected to one another. In particular lighting configurations in which multiple LED light engines are connected in a string, the placement of lenses 29 in top enclosure 20 allows for the optic spacing to be the same between LED light engines 10 as it is on one particular LED light engine 10.

Extending from the ends of the LED light engine 10 are insulated wires 12, 14. These insulated wires 12, 14 both provide electrical energy to the LEDs 60 and enable the connection of one LED light engine 10 to another. Surrounding the insulated wires 12, 14 is a sealant material 70 which holds the insulated wires 12, 14 in place and acts as a strain relief 71, 72. The sealant material 70 provides durability, protects the LED light engine 10 from moisture, and helps to hold the components of the LED light engine 10 together.

Also shown in FIG. 1 is a fastener, particularly shown as screw 18, which passes through the assembled LED light engine 10. As described in more detail below, and as shown more particularly in FIG. 2, each of the components of LED light engine 10, particularly the top enclosure 20, the printed circuit board 40, and the bottom enclosure 30, have an appropriately sized opening through which screw 18 can pass. Screw 18 is centrally positioned on LED light engine 10, substantially equidistant to and between each lens 29. Screw 18 can be used to mount LED light engine 10 to a surface.

LED light engine 10 also includes a substantially U-shaped bottom enclosure 30, the shape being more clearly illustrated in FIG. 2. Bottom enclosure 30 includes side walls 31 which extend to top enclosure 20. Side walls 31 enclose a printed circuit board 40 (as shown in FIG. 2) between top enclosure 20 and bottom enclosure 30 in the assembled LED light engine 10. The side walls 31 are located on the bottom enclosure to allow for better tolerances and consistent optics. Additionally, this location of the side walls 31 enables easier manufacturing of the integrated optics using injection molding.

FIG. 2 shows an exploded view of many of the components of the LED light engine 10. At the top of FIG. 2 is a representation of screw 18. Screw 18 is shown to have a screw head 19 and a threaded shaft 16. Also shown as part of head 19 is flange 19a that is essentially a washer-like portion below the main body of head 19. Flange 19a functions similarly to a washer to help distribute the load when screw 18 is tightened for attaching the assembled LED light engine 10 to a surface.

LED light engine 10 is shown to have three primary components: a top enclosure 20, a bottom enclosure 30, and a printed circuit board (PCB) 40 located between top enclosure 20 and bottom enclosure 30 in the assembled LED light engine 10. PCB 40 supports LEDs 60 on a top surface 24. The top portion of LED light engine 10 is top enclosure 20. Integrated into top enclosure 20 are two LED lenses 29. Lenses 29 are positioned over LEDs 60 mounted on to the top surface 24 of printed circuit board 40. Lenses 29 function to direct the illumination provided by LEDs 60.

Below screw 18 there is shown sealant material 70 which, as described above, surrounds wires 12, 14, holding them in place, and acting as a strain relief 71, 72. Sealant material 70 further provides arcuate openings on the ends of LED light engine 10 which allow passage of wires 12, 14 when LED light engine 10 is assembled. Sealant material 70 helps prevent the intrusion of moisture around wires 12, 14, as well as other areas of the assembled LED light engine 10. It is anticipated that sealant material 70 will be a thermoplastic elastomeric material.

As indicated in FIG. 2, it may be seen that the printed circuit board 40 is effectively sandwiched between the top enclosure 20 and the bottom enclosure 30. As will be explained below, in the preferred embodiment, the top enclosure 20, the printed circuit board 40, and the bottom enclosure 30 are assembled one to another before the molten plastic sealant material 70 is injected. This combination of the top enclosure 20, the printed circuit board 40 and the bottom enclosure 30 is placed into a mold (not shown). Once in the mold, the molten sealant material 70 then flows into the openings between the top enclosure 20, the printed circuit board 40, and the bottom enclosure 30. When cooled, the molten sealant material 70 seals the LED light engine from damage by moisture, provides strain relief 71, 72 around the insulated wires 12, 14, holds the wires in place within the LED light engine 10 and affixes the top enclosure 20, the printed circuit board, 40 and the bottom enclosure 30 one to another.

Shown in FIG. 2 is a top perspective view of the printed circuit board 40. Note that two LEDs 60 are located on the top surface 42. While two LEDs 60 are shown in the preferred embodiment, the number of LEDs 60 located on the top surface 42 of the printed circuit board 40 is dependent on the application of the LED light engine 10 and the amount of light required. In the middle of the printed circuit board 40 is a screw hole 48 that is sized to receive screw 18 passing therethrough. Formed around the side of the printed circuit board is an edge 49.

Various pieces of electronic componentry, to include resistors, diodes and integrated circuit chips, are located on the top surface 42 of the printed circuit board 40. Wires 12, 14 are positioned on the bottom of printed circuit board 40. If needed, some or all of the wires and electronic componentry may be placed on top of the printed circuit board 40. In the alternative, some or all of the wires and electronic componentry may be placed on the bottom of printed circuit board 40.

A top view of the top enclosure 20 is shown in FIG. 2. Therein it may be seen that lenses 29 are formed in the top surface 24 of top enclosure 20. Each of these lenses 29 is constructed, positioned, and arranged to manage the light rays emitted by the LEDs 60. In preferred embodiments, lenses 29 are free-form lenses wherein their shape is not spherical or elliptical. While two lenses 29 are shown in FIG. 2, the number of lenses depends on the number of LEDs positioned on the top surface 42 of the printed circuit board 40. Each lens 29 may be positioned over one LED 60, or in the alternative, one lens 29 may be positioned over more than one LED 60, depending on particular needs and lighting configurations. It is anticipated that the top enclosure 20 will be made using a polymethyl methacrylate (“PMMA”) or a polycarbonate (“PC”).

Shown in FIG. 2 is a top perspective view of the bottom enclosure 30. Along each long side 35 of the bottom enclosure 30 are side walls 31 which extend in a substantially vertical orientation to enclose printed circuit board 40. In preferred embodiments, side walls 31 are of a length such that they terminate coextensively with the top surface 24 of top enclosure 20. On the interior of bottom enclosure 30, adjacent to side walls 31 are channels 36. These channels 36 are sized to enable the position and the insertion of the insulated wires 12, 14 therein. On end walls 35 are located arcuate openings 13, 15 which assist in the placement of the insulated wires 12, 14 when top enclosure 20, printed circuit board 40, and bottom enclosure 30 are assembled together.

Also shown extending from the top surface 36 of the bottom enclosure 30 is a cylindrical projection 37 having a central opening therethrough that forms screw hole 38. Screw hole 38 is large enough to accommodate screw 18 which passes therethrough. As described below, a portion of top surface 36, adjacent to and along the length of side walls 31, will eventually come into physical contact with the bottom surface 43 (shown in FIG. 3) of the printed circuit board 40. It is anticipated that the bottom support enclosure 30 will be manufactured from PMMA, a polycarbonate, an ABS plastic, nylon or PVC.

Referring to FIG. 3, optionally, two-sided tape 50 may be placed on the bottom surface 33 of the bottom enclosure 30. Use of the two-sided tape 50 provides another way of attaching the assembled LED light engine 10 to a surface for assisting with attaching the LED light engine 10 to a surface. Two-sided tape 50 further includes a central opening 58 which allows for passage of screw 18 for mounting LED light engine 10 to a surface using screw 18.

Shown in FIG. 3 is a cross-section of the assembled LED light engine 10 at line 3-3 in FIG. 1. Passing through the center of the assembled LED light engine 10 is screw 18 for mounting LED light engine 10 to a surface. It is more clearly shown in FIG. 3 the spaces which sealant material 70 fills. It can be seen that sealant material 70 contacts a small portion of the printed circuit board 40. More particularly, sealant material 70 is shown to contact a portion of the side and top surface of printed circuit board 40 near the central region of the assembled LED light engine 10, as well as along the side edge and at the ends of printed circuit board 40. It is anticipated that less than 15% of the total surface area of printed circuit board 40 is in contact with sealant material 70.

Also shown in FIG. 3 is projection 37 of bottom enclosure 30 which extends upward past printed circuit board 40 and top enclosure 20 near the central region of LED light engine 10. The top edge 39 of projection 37 extends just above the top surface 24 of top enclosure 20. The area between projection 37 of bottom enclosure 30 and top enclosure 20 is sealed by being filled with sealant material 70 as shown.

It can also be seen that the bottom surface 19b of flange 19a makes contact with the top edge 39 of projection 37. This orientation creates a small gap 80 between the bottom surface 19b of flange 19a and sealant material 70. As a result of this orientation, when screw 18 is tightened for mounting LED light engine 10 to a surface, the load passes to bottom enclosure 30 through the contact between the top edge 38 of projection 37 and the bottom surface 19b of flange 19a. By preventing contact between the bottom surface 19b of flange 19a and sealant material 70, no load or force which results from tightening of screw 18 is placed on sealant material 70. This helps to protect the integrity of sealant material 70 and thereby preventing a failure in the performance of sealant material 70.

Even if sufficient torque were to be applied to screw 18, and sealant material 70 was contacted by the bottom surface 19b of flange 19a which were to result in slight damage to the surface of sealant material 70, the space filled by sealant material 70 adjacent to projection 37 is shaped so as to help prevent damage to printed circuit board 40. For example, it can be seen in FIG. 3 that the bonding path for sealant material 70 adjacent to projection 37 is not a straight line but rather forms an L-shaped path down to the area where sealant material 70 contacts the top surface of printed circuit board 40. This L-shaped bonding path helps prevent potential delamination of printed circuit board 40. Particularly, sealant material 70 could peel along the surface. If such peeling were to occur, and the bonding path were straight, it could more likely result in damage to sealant material 70 down to its contact area with printed circuit board 40. However, having a corner in the form of the L-shape means that significantly more force would be required to travel around the corner of the L-shape to reach the top surface of printed circuit board 40.

As further protection for printed circuit board 40, since the load from tightening screw 18 is also not taken by top enclosure 20, this load is not further transferred through top enclosure 20 to printed circuit board 40, and printed circuit board 40 is not subjected to significant bending forces as a result.

Also shown in FIG. 3 is a gap 82 between projection 37 and two-sided tape 50. This gap 82 helps to minimize bending, deflection and stresses to LED light engine 10 when attaching the LED light engine 10 to a surface using screw 18. For example, when screw 18 is tightened when mounting LED light engine 10, that tightening will essentially close gap 82. The gap 82 is preferably very small, less than 1 millimeter. The size and spacing of gap 82 is key because the larger that gap 82 is, the more bending stresses will be applied to LED light engine 10 when tightening screw 18. It is crucial to have a small gap in order to reduce bending of the printed circuit board 40, LEDs 60, and other electronics.

Once the LED light engine 10 components are assembled together, molten sealant material 70 is injected into the combination of the assembled top enclosure 20, the printed circuit board 40 and bottom enclosure 30. The molten sealant material 70 flows into the pathways formed when the mold is in place. The molten sealant material 70 also bonds with the edges of the printed circuit board 40. In addition, the molten sealant material 70 also chemically bonds with the bottom enclosure 30 thereby affixing the top enclosure 20, the printed circuit board 40, and the bottom enclosure 30 one to another.

The molten sealant material 70 flows into the space around the outside of the insulated wires 12, 14. A chemical bond between the flowing sealant material 70 and the insulation around the insulated wires 12, 14 is formed, thereby forming the strain relief 71, 72 section around the insulated wires 12, 14. The use of a sealant material 70 also provides moisture resistance for the LEDs 60 and the electronic componentry within the LED light engine 10.

When molten sealant material 70 is injected onto the assembled LED light engine 10, the total assembly is subject to significant crushing force. As a result of this force, printed circuit board 40 can be subject to some bending, and thus requires protection to prevent that force from causing damage such as cracking of the printed circuit board 40. In order to protect the printed circuit board 40 from these bending forces, the interface 22 between top enclosure 20 and printed circuit board 40, as well as the interface 32 between bottom enclosure 30 and printed circuit board 40 are aligned, as shown in FIG. 3. Thus, when force is applied to the top and bottom of the assembled LED light engine 10, the force that is transferred through both top enclosure 20 and bottom enclosure 30, where each enclosure contacts printed circuit board 40, is balanced. This balance of forces helps to reduce or prevent flexing of the printed circuit board 40, thereby reducing the risk of damage.

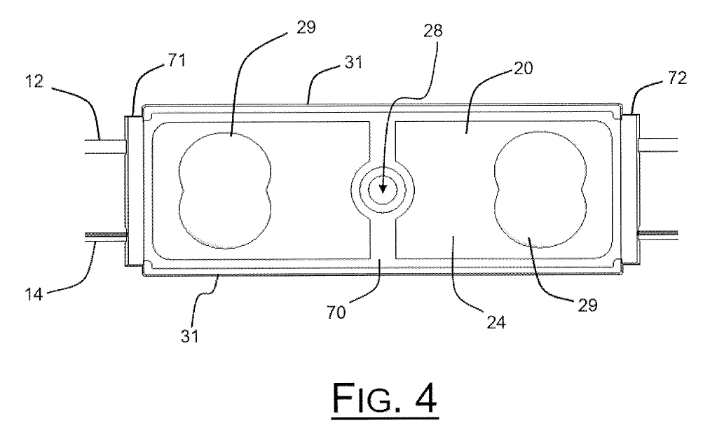

FIG. 4 is a top plan view of the assembled LED light engine 10. Notably, the spaces which are filled by sealant material 70 along a portion of the top surface 24 of top enclosure 20 can be seen, particularly along the interface of top enclosure 70 and side walls 31 of bottom enclosure 30. Also shown in FIG. 4 is an example of the free-form characteristic of the shape of lenses 29 which may be used in some embodiments.

While the present invention has been described according to its preferred embodiment, those of ordinary skill in the art will understand that modifications to the preferred embodiment may be made without departing from the scope and meaning of the appended claims.

We claim:

1. Systems and methods for providing a light emitting diode (LED) light engine, as shown and described.
